(19) United States
(12) Patent Application Publication
(10) Pub. No.: US 2026/0140141 A1
(43) Pub. Date: May 21, 2026

(54) PROBE FOR ELECTRICAL CONNECTION APPARATUS

(71) Applicant: KABUSHIKI KAISHA NIHON MICRONICS, Tokyo (JP)

(72) Inventors: Toshinaga TAKEYA, Aomori (JP); Yasutaka KISHI, Aomori (JP)

(73) Assignee: KABUSHIKI KAISHA NIHON MICRONICS, Tokyo (JP)

(21) Appl. No.: 19/405,679

(22) Filed: Dec. 2, 2025

Related U.S. Application Data
(63) Continuation of application No. PCT/JP2024/019685, filed on May 29, 2024.

(30) Foreign Application Priority Data
Jun. 14, 2023 (JP) 2023-097653

(51) Int. Cl. G01R 1/067

(52) U.S. Cl. CPC G01R 1/06727

(57) ABSTRACT

A probe for an electrical connection apparatus includes: a foot portion having an elongated shape extending in a first direction, and having a joint portion that joins to a probe substrate; an arm support portion including a support member extending in a direction intersecting the first direction in the vicinity of one end portion of the foot portion, and a diagonal member that couples from any point on the support member to a point between the other end portion and the center of the foot portion; and a cantilever-structured arm portion having a fixed end and a free end, in which a contact portion that comes into contact with an inspection object is formed at a tip of the free end and the fixed end is coupled to the arm support portion.

### CROSS-REFERENCE TO RELATED APPLICATIONS

The present application is a continuation of International Application No. PCT/JP2024/019685, filed on May 29, 2024, and based upon and claims the benefit of priority from Japanese Patent Application No. 2023-097653, filed on Jun. 14, 2023, the entire contents of which are incorporated herein by reference.

### TECHNICAL FIELD

The present disclosure relates to a probe mounted on an electrical connection apparatus.

### BACKGROUND ART

In order to inspect an inspection object, such as an integrated circuit, an electrical connection apparatus having a probe that comes into contact with the inspection object is used. In inspection using the electrical connection apparatus, a contact portion formed at one end of the probe is brought into contact with an electrode terminal of the inspection object. The other end of the probe is connected to an inspection device such as a tester through a wiring pattern. In the inspection using the inspection device, the quality of the inspection object can be determined by transmitting and receiving electric signals between the inspection object and the inspection device through the probe.

In the manufacture of an electrical connection apparatus, in order to align a plurality of probes, joint portions formed at the foot portion of each probe are pressed against respective joint pads provided on a probe substrate for joining. Laser soldering using heat is adopted for joining the joint pads and the probes.

The probe has an elongated foot portion and an arm portion elastically coupled to one end of the foot portion. More specifically, the arm portion is coupled to a support member extending in a direction orthogonal to the one end of the foot portion. The arm portion is provided with a contact portion that comes into contact with an electrode terminal of the inspection object.

### SUMMARY

As described above, the arm portion of a conventional probe is elastically coupled to the foot portion through the support member. For this reason, the moment caused by the pressure when the contact portion comes into contact with the terminal acts on the support member, and if the support member is weak in strength, the arm portion may break. Therefore, it is desirable to increase the strength by increasing the cross-sectional area of the support member.

In recent years, as the number of inspection DUTs (Device Under Test) increases, probes are required to be more densely packed, and the overall probe design tends to be miniaturized. As a result, the arm portion may be shorter than that of conventional probes. In this case, the moment caused by the pressure when the contact portion comes into contact with the terminal becomes larger than that in conventional designs, and it is considered that increasing the strength by increasing the cross-sectional area of the support member would be desirable.

Meanwhile, when the probe is soldered, a laser is irradiated from the support member side of the probe toward the joint portion. If the cross-sectional area of the support member increases, much of the heat generated during laser irradiation is dissipated through the support member, resulting in the problem of reduced laser soldering efficiency. In other words, there has been a problem that it is difficult to achieve both increasing the strength of the support member and avoiding heat dissipation during the laser irradiation.

The present disclosure has been made in view of the above problem, and an object thereof is to provide a probe for an electrical connection apparatus that is capable of increasing the coupling strength between a foot portion and an arm portion and suppressing the heat dissipation during laser irradiation.

A probe for use in an electrical connection apparatus according to an aspect of the present disclosure includes: a foot portion having an elongated shape extending in a first direction, and having a joint portion that joins to a probe substrate; an arm support portion including a support member extending in a direction intersecting the first direction in the vicinity of one end portion of the foot portion, and a diagonal member that couples from any point on the support member to a point between the other end portion and the center of the foot portion; and a cantilever-structured arm portion having a fixed end and a free end, in which a contact portion that comes into contact with an inspection object is formed at a tip of the free end and the fixed end is coupled to the arm support portion.

According to the present disclosure, it is possible to increase the coupling strength between a foot portion and an arm portion and to suppress the heat dissipation during laser irradiation.

### BRIEF DESCRIPTION OF DRAWINGS

FIG. 1 is a side view of a probe according to a first embodiment.

FIG. 2 is a side view illustrating a modified example of the probe illustrated in FIG. 1.

FIG. 3 is a side view of a probe according to a second embodiment.

FIG. 4 is a side view of a probe according to a third embodiment.

FIG. 5 is a side view of a probe according to a first comparative example.

FIG. 6 is a side view of a probe according to a second comparative example.

### DESCRIPTION OF EMBODIMENTS

Embodiments will be described below with reference to the drawings. The same or similar elements illustrated in the drawings are denoted by the same or similar reference numerals. The embodiments described below exemplify devices and methods for embodying the technical idea of the present disclosure. In the embodiments of the present disclosure, the material, shape, structure, arrangement, and the like of the components are not limited to the following description.

### First Embodiment

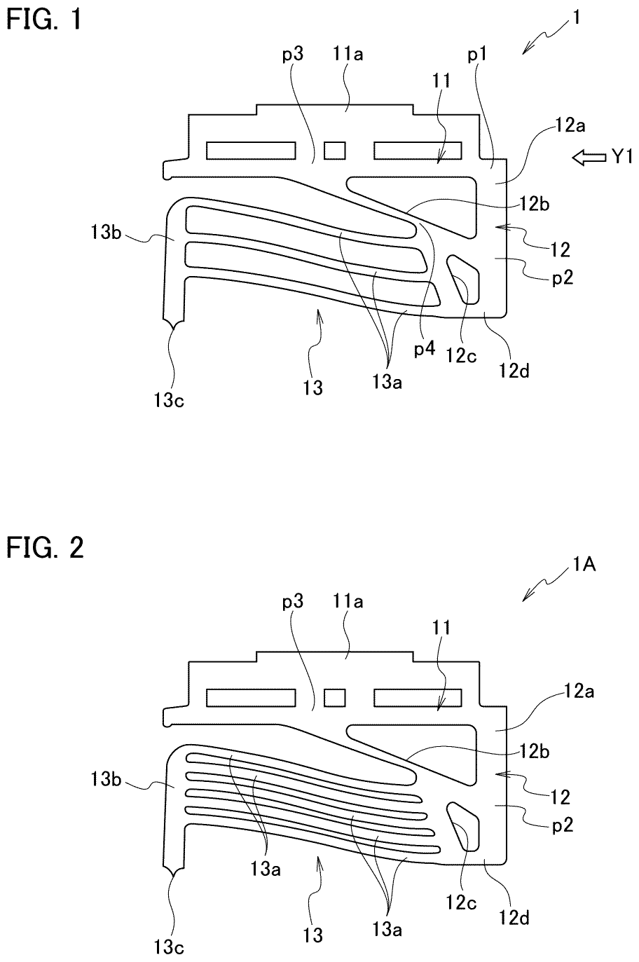

FIG. 1 is a side view of a probe 1 for an electrical connection apparatus (hereinafter simply referred to as “probe 1”) according to a first embodiment. As illustrated in FIG. 1, the probe 1 includes a foot portion 11, an arm support portion 12, and an arm portion 13. The probe 1 has a flat plate shape having a desired thickness in a direction orthogonal to the plane of the page. The probe 1 is mounted on an electrical connection apparatus and is made of a conductive material. In the probe 1, the electrode terminal of the inspection object is electrically connected to the probe substrate by coupling a joint portion 11a to the probe substrate and bringing a contact portion 13c into contact with the electrode terminal of the inspection object, as described below.

The foot portion 11 has an elongated shape. Hereinafter, the direction in which the foot portion 11 extends (left-right direction in the figure) is defined as the first direction. The tip direction of the contact portion 13c is defined as the lower side, and the opposite side thereof is defined as the upper side. That is, the up-down direction in the figure corresponds to the upper side and the lower side of the probe 1, respectively.

The joint portion 11a is formed along one side of the foot portion 11. The probe 1 and the probe substrate can be electrically connected to each other by joining the joint portion 11a to a joint pad provided on the probe substrate (not illustrated).

The joint portion 11a is formed in the shape of a convex portion projecting upward from the upper side of the foot portion 11, and is positioned, for example, above the upper end portion of a diagonal member 12b. Note that the joint portion 11a is not limited to being positioned above the upper end portion of the diagonal member 12b. Additionally, a plurality of joint portions 11a may be formed.

The foot portion 11 and the joint pad are irradiated with a laser beam from the direction of the arrow Y1 in the figure, and the foot portion 11 and the joint pad are electrically coupled to each other by soldering. The irradiation direction of the laser beam is not limited to the Y1 direction.

The arm support portion 12 supports the arm by coupling the foot portion 11 with the arm portion 13. The arm support portion 12 includes a support member 12a, the diagonal member 12b, a connection member 12c, and a bottom member 12d.

The support member 12a has an elongated shape, and an upper end portion thereof is coupled to one end portion p1 of the foot portion 11 (in the vicinity of one end portion) in a substantially orthogonal direction (that is, in a direction intersecting the first direction). The lower end portion of the support member 12a is coupled to one end of the bottom member 12d extending in a direction orthogonal to the support member 12a (that is, in a direction along the first direction).

The diagonal member 12b couples any point p2 on the lower side of the support member 12a to the center point p3 on the foot portion 11. That is, one end of the diagonal member 12b is coupled to any point on the support member 12a, and the other end is coupled to the center of the foot portion 11. The diagonal member 12b has a narrow width in the vicinity of a point p4 near the central portion thereof, and changes such that the width gradually increases from the point p4 toward the connection point p3 on the foot portion 11. Furthermore, the width gradually increases from the point p4 toward the coupling point p2. The point p4 and the other end of the bottom member 12d are coupled to each other by the connection member 12c.

The arm portion 13 includes a plurality of arms 13a (in the figure, there are three arms 13a), a tip member 13b coupled to an end portion of each arm 13a, and the contact portion 13c formed at the lower end of the tip member 13b and projecting downward. Each arm 13a has an elongated, narrow shape extending in the first direction. The respective arms 13a are arranged substantially in parallel, and the right end portion of each arm 13a is coupled to the connection member 12c. Note that the arms 13a are not limited to being arranged in parallel.

The right end portion of each arm 13a is a fixed end at which the arm portion 13 is coupled to the arm support portion 12. The left end portion of each arm 13a is a free end formed with the contact portion 13c. That is, the arm portion 13 has a cantilever structure with a fixed end and a free end. In this cantilever structure, the contact portion 13c that comes into contact with the inspection object is formed at the tip of the free end and the fixed end is coupled to the arm support portion 12.

Further, the length (hereinafter, it may be referred to as the arm length) from the contact portion 13c to the support member 12a in the first direction is substantially the same as the length (hereinafter, it may be referred to as the foot length) of the foot portion 11 in the first direction. The arm length is not limited to being substantially the same as the foot length, and may be longer than the foot length or shorter than the foot length.

In the probe 1 according to the first embodiment described above, the lower point p2 on the support member 12a and the center point p3 on the foot portion 11 are coupled by the diagonal member 12b. For this reason, even when the contact portion 13c of the arm portion 13 is displaced in the up-down direction and a moment is generated in the support member 12a, the arm portion 13 is firmly fixed by the arm support portion 12, thereby increasing the coupling strength between the foot portion 11 and the arm portion 13.

Further, the width (corresponding to the cross-sectional area) of the support member 12a is substantially equal to that of a conventional probe. Therefore, when a laser beam is irradiated from the direction indicated by the arrow Y1 in FIG. 1 for soldering, it is possible to suppress the heat dissipation from the laser irradiation through the support member 12a, thereby improving the soldering efficiency using the laser beam. That is, it is possible to increase the coupling strength between the foot portion 11 and the arm portion 13 and to suppress heat dissipation during laser irradiation.

Both end portions of the diagonal member 12b are formed so as to increase in width from the central portion (point p4) of the diagonal member 12b toward both end sides. That is, the width of the diagonal member 12b gradually increases from the central portion toward the connection point p3. This enables stress applied to both end portions of the diagonal member 12b, which is generated when the probe 1 is brought into contact with the DUT, to be dispersed. Therefore, breakage of the probe 1 can be suppressed.

By forming the joint portion 11a in a convex shape, the joint area can be made smaller than that of the foot portion 11, so that joining can be made with a relatively small amount of solder. Therefore, even if heat from laser irradiation is dissipated, the solder can be sufficiently melted without increasing the laser output. Furthermore, by positioning the joint portion 11a above the diagonal member 12b, stress applied to the diagonal member 12b during inspection can be efficiently transmitted to the joint portion 11a.

Although the probe 1 according to the first embodiment illustrates an example in which the arm portion 13 includes three arms 13a, the number of arms 13a is not limited to three. For example, as illustrated in FIG. 2, five arms 13a may be provided.

### Second Embodiment

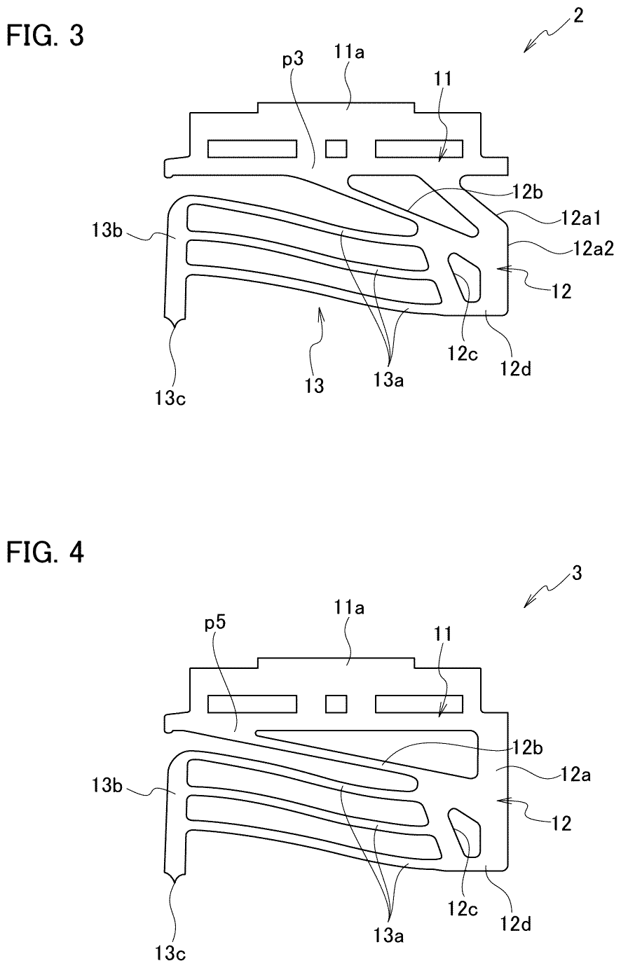

Next, a second embodiment will be described. FIG. 3 is a side view illustrating the configuration of a probe 2 according to the second embodiment. The probe 2 according to the second embodiment differs from the probe 1 according to the first embodiment in that the support member 12a is configured of a first support member 12a1 and a second support member 12a2.

The first support member 12a1 is coupled to the vicinity of the right end portion (in the vicinity of one end portion) of the foot portion 11 in an oblique direction (that is, a direction intersecting the first direction), and the second support member 12a2 is connected to the first support member 12a1 at a fixed angle. Other than this, the configuration is the same as that of the probe 1 according to the first embodiment. In the probe 2 according to the second embodiment, as in the probe 1 according to the first embodiment, it is possible to increase the coupling strength between the foot portion 11 and the arm portion 13 and to suppress heat dissipation during laser irradiation.

### Third Embodiment

Next, a third embodiment will be described. FIG. 4 is a side view illustrating the configuration of a probe 3 according to the third embodiment. The probe 3 according to the third embodiment differs from the probe 1 according to the first embodiment in that one end portion of the diagonal member 12b is coupled to a point p5 on the left end portion of the foot portion 11. That is, the diagonal member 12b is coupled to the other end portion of the foot portion 11.

In the probe 3 according to the third embodiment, as in the probe 1 according to the first embodiment, it is possible to increase the coupling strength between the foot portion 11 and the arm portion 13 and to suppress heat dissipation during laser irradiation.

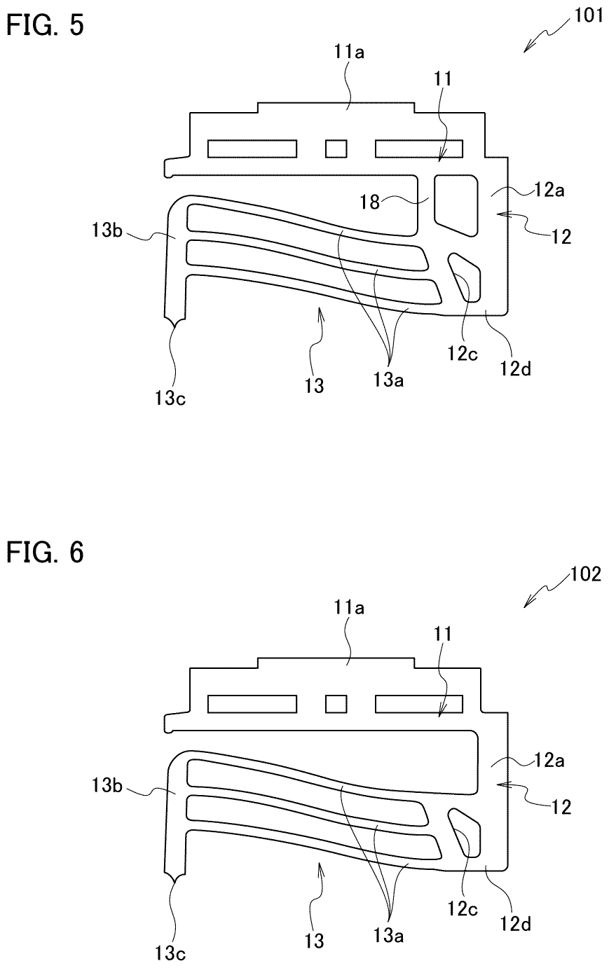

FIGS. 5 and 6 are side views illustrating the configurations of the probes according to a first comparative example and a second comparative example, and the first to third embodiments described above and first and second comparative examples will be compared and described below.

As illustrated in FIG. 5, the probe 101 according to the first comparative example includes a coupling member 18 that couples an end portion of the connection member 12c provided on the arm support portion 12 to the foot portion 11. However, the coupling member 18 does not couple at any point between the left end portion (the other end portion) and the center of the foot portion 11.

As illustrated in FIG. 6, the probe 102 according to the second comparative example is different from the probe 1 according to the first embodiment in that it is not provided with the diagonal member 12b that couples the arm support portion 12 to the foot portion 11.

Heat due to laser irradiation moves from the joint portion 11a to the support member 12a through the foot portion 11. That is, in order to suppress heat dissipation from laser irradiation, it is required that the coupling portion between the coupling member 18 and the foot portion 11 be sufficiently separated from the support member 12a. Meanwhile, since the coupling member 18 extends in the up-down direction, the arm length of the arm portion 13 becomes shorter as the coupling member 18 is positioned further away from the support member 12a. When the size of a probe is limited due to the recent demand for probe miniaturization, it becomes difficult to secure sufficient arm length so as to ensure adequate needle pressure if the coupling member 18 is used.

Further, the diagonal member 12b is not provided in the first and second comparative examples illustrated in FIGS. 5 and 6. As a result, the coupling strength between the foot portion 11 and the arm portion 13 cannot be increased, and a moment due to the pressure when the contact portion 13c comes into contact with the terminal acts on the support member 12a, resulting in problems such as breakage of the coupling portion between the support member 12a and the arm portion 13.

By providing the diagonal member 12b, the probes 1, 2, and 3 of the first to third embodiments can achieve both sufficient separation of the coupling portion between the diagonal member 12b and the foot portion 11 from the support member 12a, and sufficient arm length.

The first to third embodiments of the present disclosure are provided with the arm support portion 12 including: the support member 12a extending in a direction intersecting the first direction in the vicinity of one end portion (p1 in FIG. 1) of the foot portion 11; and the diagonal member 12b coupling from any point (p2 in FIG. 1) on the support member 12a to a connection point (p3 in FIG. 1) between the other end portion and the center of the foot portion 11. Since the arm support portion 12 includes the diagonal member 12b, even when the contact portion 13c of the arm portion 13 is displaced in the up-down direction and a moment is generated in the support member 12a, the arm portion 13 is firmly fixed by the arm support portion 12. Furthermore, since the arm support portion 12 includes the diagonal member 12b, the width (corresponding to the cross-sectional area) of the support member 12a can be made substantially equal to that of a conventional probe. Therefore, when the laser beam is irradiated from the direction indicated by the arrow Y1 in FIG. 1 for soldering, it is possible to suppress the heat dissipation from the laser irradiation through the support member 12a, thereby improving the soldering efficiency using the laser beam. That is, it is possible to increase the coupling strength between the foot portion 11 and the arm portion 13 and to suppress heat dissipation during laser irradiation.

Although the embodiments of the present disclosure have been described, it should not be understood that the statements and drawings which form a part of this disclosure are intended to limit the disclosure. Various alternative embodiments, examples and operating techniques will be apparent to those skilled in the art from this disclosure.

1. A probe for use in an electrical connection apparatus, comprising:
a foot portion having an elongated shape extending in a first direction, and having a joint portion that joins to a probe substrate;
an arm support portion including a support member extending in a direction intersecting the first direction in a vicinity of one end portion of the foot portion, and a diagonal member that couples from any point on the support member to a point between the other end portion and the center of the foot portion; and
a cantilever-structured arm portion having a fixed end and a free end, in which a contact portion that comes into contact with an inspection object is formed at a tip of the free end and the fixed end is coupled to the arm support portion.

2. The probe for use in an electrical connection apparatus according to claim 1, wherein the diagonal member is coupled to the center of the foot portion.

3. The probe for use in an electrical connection apparatus according to claim 1,
wherein the diagonal member is coupled to the other end portion of the foot portion.

4. The probe for use in an electrical connection apparatus according to claim 1,
wherein a width of the diagonal member gradually increases from a central portion toward a connection point on the foot portion.
